(19) United States
(12) Patent Application Publication
(10) Pub. No.: US 2013/0329296 A1
(43) Pub. Date: Dec. 12, 2013

(54) DEVICE FOR GROWING SAPPHIRE INGOT AT HIGH SPEED AND SAPPHIRE COVER GLASS HAVING EXCELLENT OPTICAL PROPERTIES

(71) Applicant: HON HAI PRECISION INDUSTRY CO., LTD., New Taipei (TW)

(72) Inventors: Ga-Lane CHEN, Santa Clara, CA (US); Chung-Pei WANG, New Taipei (TW)

(73) Assignee: HON HAI PRECISION INDUSTRY CO., LTD., New Taipei (TW)

(21) Appl. No.: 13/740,147

(22) Filed: Jan. 11, 2013

(30) Foreign Application Priority Data
Jun. 12, 2012 (TW) 101120973

(51) Int. Cl. C30B 15/00; G02B 1/11; C30B 15/36; C30B 15/14; C30B 15/20; C30B 15/30

(52) U.S. Cl. CPC C30B 15/00; C30B 15/20; C30B 15/30; C30B 15/36; C30B 15/14; G02B 1/11
USPC 359/601; 117/216; 117/202; 117/201

(57) ABSTRACT

A device grows sapphire ingots by dipping a sapphire seed into molten aluminum oxide and lifting and spinning the sapphire seed from the molten aluminum oxide to cause the molten aluminum oxide adhering to the sapphire. Meanwhile, the device controls temperature such that the molten aluminum oxide is crystallized on the sapphire seed which is gradually cooled down to a room temperature. The device also includes a housing and air controller for providing desire air conditions for growing the sapphire ingot.

### BACKGROUND

1. Technical Field

The present disclosure relates to sapphire growing technologies and, particularly, to a device for growing a sapphire ingot at a high speed and a cover glass made of sapphire and having excellent optical properties.

2. Description of Related Art

Due to excellent mechanical and optical properties, sapphires are one of preferred materials for cover glasses of lens modules. The sapphire is typically made by a kyropoulos method with a low crystallization rate, and increases cost of the sapphire and the cover glass. In addition, a transmissivity of the sapphire at visible light wavelengths is often less than satisfactory (<86%), which degrades the optical quality of the cover glass.

Therefore, it is desirable to provide a device for growing a sapphire ingot and a cover glass, which can overcome the above-mentioned problems.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

FIG. 1 is a schematic view of a device for growing a sapphire ingot, according to an embodiment, which is in a first state.

FIG. 2 is similar to FIG. 1, but showing the device in a second state.

FIG. 3 is similar to FIG. 1, but showing the device in a third state.

FIG. 4 is a schematic view of a cover glass, according to another embodiment.

### DETAILED DESCRIPTION

Embodiments of the present disclosure will now be described in detail with reference to the drawings.

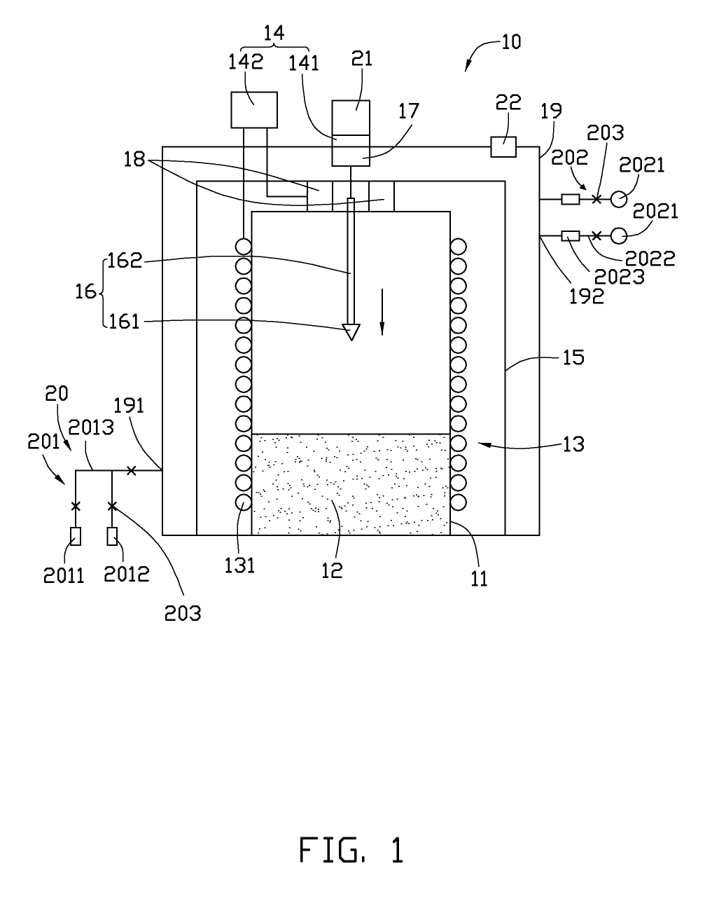

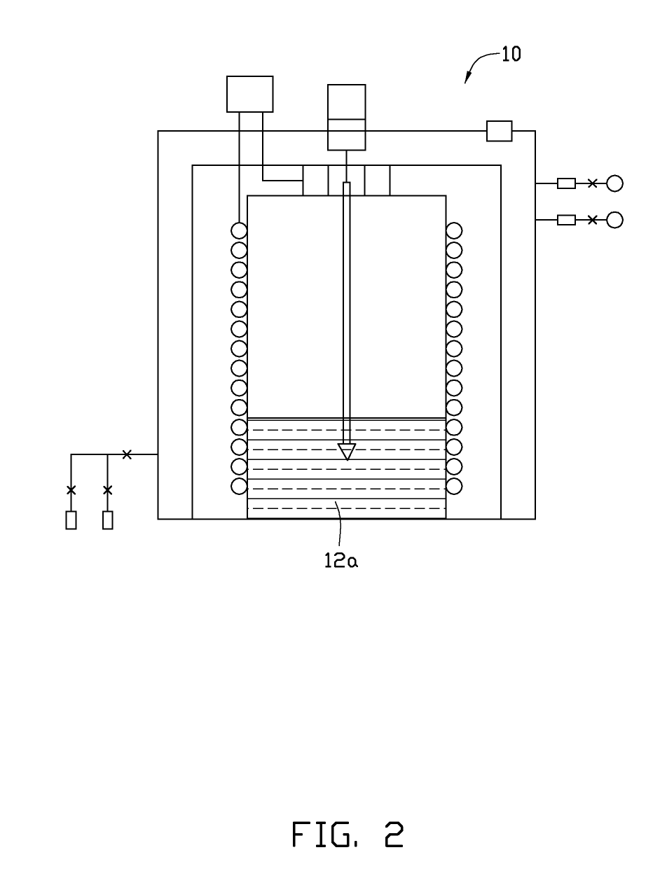

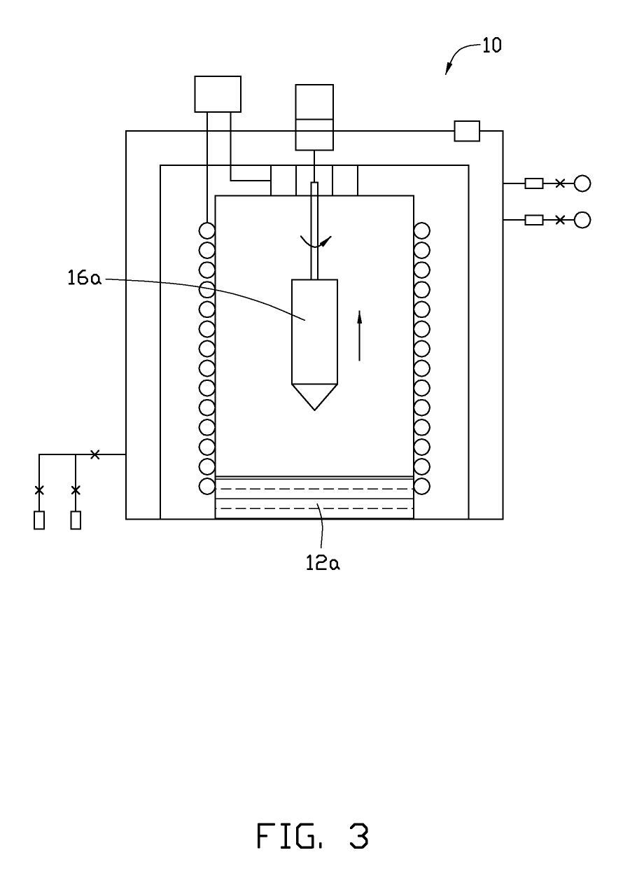

Referring to FIGS. 1-3, a device 10 for growing a sapphire ingot 16a, according to an embodiment, includes a crucible 11, an aluminum oxide material 12, a heater 13, a temperature controller 14, a heat preservation shell 15, a sapphire seed assembly 16, a driver 17, a post-heating device 18, a housing 19, and an air controller 20.

The aluminum oxide material 12 is received in the crucible 11. Sapphire is a gemstone variety of the mineral corundum, and has a hexagonal crystal structure. The main chemical component of sapphire is aluminum oxide. Therefore, the aluminum oxide material 12 is used as the raw material of the sapphire ingot 16a. The crucible 11 can be made of tungsten which can withstand a relative high temperature. Specifically, a melting point of tungsten is higher than a melting point of aluminum oxide which is about 2050 degrees Celsius.

The heater 13 includes a coil 131 winding the crucible 11. The temperature controller 14 is configured for controlling the heater 13 to heat the crucible 11 utilizing the electromagnetic induction effect of the coil 131 such that the aluminum oxide material 12 is molten into a liquid 12a and a temperature above the liquid 12a is lower than a melting point of the aluminum oxide material 12 and gradually decreases from the liquid 12a to a top of the crucible 11. In the embodiment, the temperature controller 14 includes a thermometer 141 and a controller 142. The thermometer 141 is configured for measuring the temperature in the crucible 11. The controller 142 is configured for controlling the heater 13 to heat the crucible 11 based upon measuring results of the thermometer 141. The controller 142 can apply electric currents of different levels of power to different parts of the coil 131 to heat the different parts of the crucible 11 at different levels to obtain desired temperatures of the different parts of the crucible 11.

The heat perseveration shell 15 encloses the crucible 11 configured for maintaining a constant temperature filed in the crucible 11. In addition, the heat preservation shell 15 is made of non-radiation material and thus can provide shielding against electromagnetic interference.

The sapphire seed assembly 16 includes a sapphire seed 161 and a holder 162 holding the sapphire seed 161. The holder 162 is a rod arranged substantially perpendicular to a top surface of the liquid 12a and holds the sapphire seed 161 at an end that is adjacent to the liquid 12a. A growing axis of the sapphire seed 161 can be the a axis (11 ^{2̅}0), c axis (0001), or m axis (10 ^{1̅}0).

The driver 17 is configured for driving the sapphire seed assembly 16 to move such that the sapphire seed 161 dips into the liquid 12a, and then lifts out of the liquid 12a and the crucible 11 and spins at predetermined speeds. As such, the liquid 12a adhering to the sapphire seed 16 is shaped cylinder-like and is crystallized as the sapphire seed 161 ascends and the temperature gradually decreases to form the sapphire ingot 16a. In the embodiment, the driver 17 can be installed within the housing 19. For example, the driver 17 can be suspended to the ceiling of the housing 19 and can include a linear motor (or cylinder) and a rotational motor for driving the holder 162 to move linearly and spin.

The post-heating device 18 is configured for heating the sapphire ingot 16a out of the crucible 11 such that the sapphire ingot 16a can be gradually cooled down to the room temperature. The post-heating device 18 can be positioned above the crucible 11 and can be made of metal oxide having a high melting point, such as aluminum oxide or ceramic, or can be a multi-layer metal reflector made of molybdenum or platinum. The controller 142 is also connected to the post-heating device 18 and can control the post-heating device 18.

The housing 19 encloses the heat preservation shell 15 and is configured for providing air conditions and electromagnetic interference shielding for growing the sapphire ingot 16a. The housing 19 defines an air outlet 191 and an air inlet 192. The air outlet 191 is positioned close to a bottom of the housing 19 and the air inlet 192 is positioned close to a top of the housing 19.

The air controller 20 is configured for vacuumizing the housing 19 and introducing desired gases into the housing 19 to control air conditions within the housing 19. The air controller 20 includes an air pump system 201 and an air introducer 202.

The air pump system 201 includes a mechanical pump 2011, a turbine pump 2012, and a first pipe system 2013. The first pipe system 2013 communicates the housing 19 with the mechanical pump 2011 and the turbine pump 2012 via the air outlet 191 and has a number of air valves 203. The air valves 203 are configured for individually connecting or disconnecting the housing 19 to the air pump 2011 and the turbine pump 2012. In operation, the air valves 203 are operated such that the housing 19 is connected to the mechanical pump 2011, but disconnected from the turbine pump 2012. Then the housing 19 is vacuumized by the mechanical pump 2011. Next, the air valves 203 are operated such that the housing 19 is connected to the turbine pump 2012, but disconnected from the mechanical pump 2011. The housing 19 is further vacuumized by the turbine pump 2012. Finally, the air valves 203 are operated such that the housing 19 is disconnected from both the mechanical pump 2011 and the turbine pump 2012.

The air introducer 202 includes a number of gas sources 2021 and a second pipe system 2022. The gas sources 2021 are configured for providing gases for growing the sapphire ingot 16a, such as argon and/or helium. The second pipe system 2022 communicates the housing 19 with the gas sources 2021 via the air inlet 192 and also has a number of air valves 203. The air valves 203 are configured for selectively connecting or disconnecting the air sources 2021 with the housing 19. The air introducer 202 can further includes a mass flow controller 2023 installed at the second pipe system 2022, which is configured for control the flow of the gases.

The device 10 also includes a camera 21 and a residual gas analyzer 22. The camera 21 is configured for monitoring the growing of the sapphire ingot 16a. The residual gas analyzer 22 is configured for analyzing the components of the gases in the housing 19.

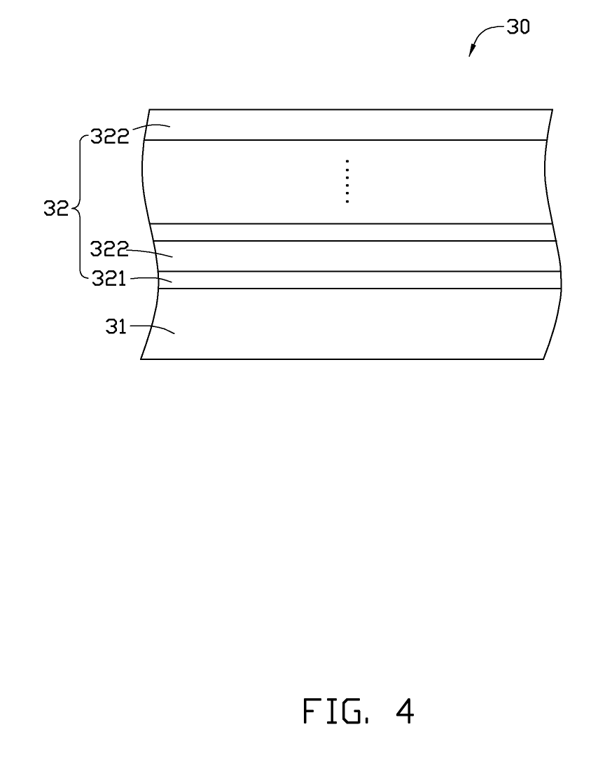

Referring to FIG. 4, a cover glass 30, according to an embodiment, includes a substrate 31 and an anti-reflection film 32 coated on the substrate 31. The substrate 31 is made of the sapphire ingot 16a. The anti-reflection film 32 includes a number of high refractive layers 321 and a number of low refractive layers 322 alternately stacked on the substrate 31. A structure of the anti-reflection layer 32 can be represented by (xHyL)ⁿ, which indicates that the anti-reflection film 32 has “n” repetitions of (xHyL), wherein n is a positive inter and satisfies the condition: 4≦n≦8. Each repetition of (xHyL) has the high refractive layer xH of an optical thickness “xλ/4” and the low index layer yL of an optical thickness “yλ/4”, wherein x and y satisfy the conditions: 1<x<2 and 1<y<2, and λ is a central working wavelength of the anti-reflection film 32. The first high refractive layer 321 is in contact with the substrate 31 and the first low refractive layer 322 is in contact with the first high refractive layer 321.

The high refractive layers 321 can be made from titanium dioxide with a refractive index of about 2.705. The low refractive layers 322 can be made from silicon dioxide with a refractive index of about 1.499.

A crystallization rate of the sapphire ingot 16a grown in the device 10 greatly increases, as compared to a kyropoulos method. By employing the anti-reflection film 32, a transmissivity of the cover glass 30 can be enhanced to about 99.5%.

It will be understood that the above particular embodiments are shown and described by way of illustration only. The principles and the features of the present disclosure may be employed in various and numerous embodiment thereof without departing from the scope of the disclosure as claimed. The above-described embodiments illustrate the possible scope of the disclosure but do not restrict the scope of the disclosure.

What is claimed is:

1. A device, comprising:
a crucible;
an aluminum oxide material received in the crucible;
a heater;
a temperature controller configured for controlling the heater to heat the crucible such that the aluminum oxide material is molten into a liquid and a temperature above the liquid is smaller than a melting point of the aluminum oxide material and gradually decreases from the liquid to a top of the crucible;
a heat preservation shell enclosing the crucible and configured for keeping a temperature filed within the crucible unchanged;
a sapphire seed assembly comprising a sapphire seed;
a driver configured for driving the sapphire seed assembly to move such that the sapphire seed dips into the liquid, and lifts out of the liquid and the crucible, and spins at predetermined speeds to cause that the liquid adheres to the sapphire seed, and is shaped cylinder-like, and is crystallized as the sapphire seed ascends and the temperature gradually decreases to form a sapphire ingot;
a post-heating device configured for heating the sapphire ingot out of the crucible such that the sapphire ingot is gradually cooled down to a room temperature;
a housing encloses the heat preservation shell and configured for providing air conditions and electromagnetic interference shielding for growing the sapphire ingot; and
an air controller configured for vacuumizing the housing and introducing desire gases into the housing to control the air conditions within the housing.

2. The device of claim 1, wherein the crucible is made of tungsten.

3. The device of claim 1, wherein the heater includes a coil winding around the crucible, and the temperature controller controls the heater by applying electric currents of different levels of power to different parts of the coil to heat the different parts of the crucible at different levels to obtain desired temperatures of the different parts of the crucible.

4. The device of claim 1, wherein the temperature controller comprising a thermometer and a controller, the thermometer is configured for measuring the temperature in the crucible, and the controller is configured for controlling the heater to heat the crucible, based upon measuring results of the thermometer.

5. The device of claim 1, wherein the heat preservation shell is made of non-radiation material.

6. The device of claim 1, wherein the sapphire seed assembly comprises a holder for holding the sapphire seed, the holder is a rod arranged substantially perpendicular to a top surface of the liquid and holds the sapphire seed at an end that is adjacent to the liquid.

7. The device of claim 1, wherein a growing axis of the sapphire seed is selected from the group consisting of a axis (11 ^{2̅}0), c axis (0001), and m axis (10 ^{1̅}0).

8. The device of claim 1, wherein the temperature controller is connected to the post-heating device and configured for controlling the post-heating device.

9. The device of claim 1, wherein the post-heating device is positioned above the crucible and is made of metal oxide having a high melting point.

10. The device of claim 9, wherein the metal oxide is aluminum oxide or ceramic.

11. The device of claim 1, wherein the post-heating device is positioned above the crucible and comprises a multi-layer reflector

12. The device of claim 11, wherein the multi-layer metal reflector is made of molybdenum or platinum.

13. The device of claim 1, wherein the housing defines an air outlet and an air inlet; the air outlet is positioned close to a bottom of the housing, and the air inlet is positioned close to a top of the housing.

14. The device of claim 13, wherein the air controller comprises an air pump system, the air pump system includes a mechanical pump, a turbine pump, and a first pipe system, the first pipe system communicates the housing with the mechanical pump and the turbine pump via the air outlet and has a plurality of first air valves, the first air valves are configured for individually connecting or disconnecting the housing to the air pump and the turbine pump.

15. The device of claim 13, wherein the air controller comprises an air introducer, the air introducer comprises a plurality of gas sources and a second pipe system, the gas sources are configured for providing gases for growing the sapphire ingot, the second pipe system communicates the housing with the gas sources via the air inlet and has a plurality of second air valves, the second air valves are configured for selectively connecting or disconnecting the air sources with the housing.

16. The device of claim 15, wherein the air introducer further comprises a mass flow controller installed at the second pipe system, and the mass flow controller is configured for control the flow of the gases.

17. The device of claim 1, further comprising a camera for monitoring the growing of the sapphire ingot.

18. The device of claim 1, further comprising a residual gas analyzer for analyzing the components of the gases in the housing.

19. A cover glass, comprising:
a substrate; and
an anti-reflection film coated on the substrate;
wherein the substrate is made of the sapphire ingot, the anti-reflection film comprises a plurality of high refractive layers and a plurality of low refractive layers alternately stacked on the substrate, a structure of the anti-reflection layer is represented by (xHyL)ⁿ, which indicates that the anti-reflection film has “n” repetitions of (xHyL), wherein n is a positive inter and satisfies the condition: 4≦n≦8, each repetition of (xHyL) has the high refractive layer xH of an optical thickness “xλ/4” and the low index layer yL of an optical thickness “yλ/4”, wherein x and y satisfy the conditions: 1<x<2 and 1<y<2, and λ is a central working wavelength of the anti-reflection film, and a first one the high refractive layers is in contact with the substrate and a first one of the low refractive layers is in contact with the first high refractive layer.

20. The cover glass of claim 19, wherein the high refractive layers are made from titanium dioxide and the low refractive layers are made from silicon dioxide.
